(19) United States
(12) Patent Application Publication
(10) Pub. No.: US 2026/0189855 A1
(43) Pub. Date: Jul. 2, 2026

(54) SELF-ADAPTIVE MEMS LOUDSPEAKER DRIVING CIRCUIT

(71) Applicants: ZILLTEK TECHNOLOGY (SHANGHAI) CORP., Shanghai (CN); ZILLTEK TECHNOLOGY CORP., Hsinchu City (TW)

(72) Inventors: Jinghua YE, Shanghai (CN); Zhenqi QIU, Shanghai (CN); Zihao YE, Shanghai (CN)

(21) Appl. No.: 19/315,013

(22) Filed: Aug. 29, 2025

(30) Foreign Application Priority Data
Dec. 26, 2024 (CN) 202411954407.8

(51) Int. Cl. H04R 17/00; H03F 3/45

(52) U.S. Cl. CPC H04R 17/00; H03F 3/45475; H03F 2200/03; H04R 2201/003

(57) ABSTRACT

The invention relates to the technical field of micro electromechanical system, in particular to a self-adaptive MEMS (micro electromechanical system) loudspeaker driving circuit, which comprises: an amplification unit, an input end of the amplification unit is connected with an audio input signal, and an output signal of the amplification unit is connected with an MEMS loudspeaker; a boosting unit, an input end of the boosting unit is connected with a power supply voltage, and an output end of the boosting unit outputs at least one boosting voltage; the MEMS loudspeaker is selectively operable at a first boosting voltages or at the power supply voltage. The MEMS loudspeaker can selectively operable at the boosting voltage or at the input voltage, can adaptively select a working voltage, does not need to work under a high voltage for a long time, and is beneficial to improving the anti-electromagnetic interference capability.

### RELATED APPLICATION INFORMATION

This application claims benefit of priority to Chinese Patent Application No.: 202411954407.8, filed Dec. 26, 2024, of which full contents are incorporated herein by reference.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field of the Invention

The present invention relates to the field of micro electromechanical technology, and in particular, to a MEMS loudspeaker drive circuit.

### Description of the Related Art

MEMS loudspeakers, due to advantages such as miniaturization, low power consumption, and high reliability, are gradually replacing traditional dynamic or balanced armature speakers. However, the circuit characteristics of prior-art MEMS loudspeakers exhibit a capacitive load, requiring a drive voltage of 15V to 20V high voltage with large signal amplitude, which generates high slew rates and results in poor electromagnetic interference immunity of the circuit.

### SUMMARY OF THE INVENTION

Based on the foregoing description, the present invention provides a self-adaptive MEMS loudspeaker driving circuit.

A self-adaptive MEMS loudspeaker driving circuit, comprising:
an amplification unit, an input end of the amplification unit is connected with an audio input signal, and an output signal of the amplification unit is connected with an MEMS loudspeaker;
a boosting unit, an input end of the boosting unit is connected with a power supply voltage, and an output end of the boosting unit outputs at least one boosting voltage;
the MEMS loudspeaker is selectively operable at one of the boosting voltages or at the power supply voltage.

The self-adaptive MEMS loudspeaker driving circuit of the invention, comprising a selection unit, which selectively outputs the one of the boosting voltages or the power supply voltage under the action of a control signal.

The self-adaptive MEMS loudspeaker driving circuit of the invention, comprising an amplitude detection unit, wherein the amplitude detection unit detects an amplitude of the audio input signal, and an output terminal of the amplitude detection unit outputs the control signal.

The self-adaptive MEMS loudspeaker driving circuit of the invention, the amplitude detection unit outputs a first signal when the amplitude of the audio input signal is greater than a reference amplitude, and outputs a second signal when the amplitude of the audio input signal is less than the reference amplitude;
the selection unit outputs a first boosting voltage under action of the first signal, and outputs the power supply voltage under action of the second signal.

The self-adaptive MEMS loudspeaker driving circuit of the invention, the amplitude detection unit outputs a first signal when the amplitude of the audio input signal is greater than a first reference amplitude, outputs a second signal when the amplitude of the audio input signal is greater than the first reference amplitude and less than a second reference amplitude, and outputs a third signal when the amplitude of the audio input signal is greater than the second reference amplitude and less than a third reference amplitude;
the selection unit outputs a first boosting voltage under action of the first signal, outputs a second boosting voltage under action of the second signal, and outputs the power supply voltage under action of the third signal.

The self-adaptive MEMS loudspeaker driving circuit of the invention, a first input terminal of the amplification unit is connected to the audio input signal through a first capacitor, and a second input terminal of the amplification unit is connected to a ground terminal through a second capacitor.

The self-adaptive MEMS loudspeaker driving circuit of the invention, a first output terminal of the amplification unit is connected to a first input terminal of the MEMS loudspeaker through a third capacitor, and a second output terminal of the amplification unit is connected to a second input terminal of the MEMS loudspeaker through a fourth capacitor.

The self-adaptive MEMS loudspeaker driving circuit of the invention, a first input terminal of the MEMS loudspeaker is connected to an output terminal of the selection unit through a first resistor, and a second input terminal of the MEMS loudspeaker is connected to a ground terminal through a second resistor.

The self-adaptive MEMS loudspeaker driving circuit of the invention, the amplification unit is a differential amplifier, and the boosting unit is a BOOST power converter or a charge pump.

The self-adaptive MEMS loudspeaker driving circuit of the invention, the power supply voltage ranges from 3.3 V to 4.2 V or from 1.5 V to 3 V.

The beneficial technical effects are as follows: the MEMS loudspeaker can selectively operable at the boosting voltage or at the input voltage, can adaptively select a working voltage, does not need to work under a high voltage for a long time, and is beneficial to improving the anti-electromagnetic interference capability.

### DESCRIPTION OF THE DRAWINGS

FIG. 1 is a principle block diagram of a self-adaptive MEMS loudspeaker driving circuit according to an embodiment of the present invention;

FIG. 2 is a principle block diagram of a self-adaptive MEMS loudspeaker driving circuit according to another embodiment of the present invention.

### DETAILED DESCRIPTION

The technical solutions in the embodiments of the present invention will be clearly and completely described below in conjunction with the accompanying drawings in the embodiments of the present invention. It is apparent that the described embodiments are merely a part of the embodiments of the present invention, rather than all of them. All other embodiments obtained by a person of ordinary skill in the art based on the embodiments of the present invention without making creative efforts shall fall within the protection scope of the present invention.

It should be noted that, in the absence of conflict, the embodiments in the present invention and the features in the embodiments may be combined with each other.

The present invention will be further described below in conjunction with the accompanying drawings and specific embodiments, but such description shall not be construed as limiting the invention.

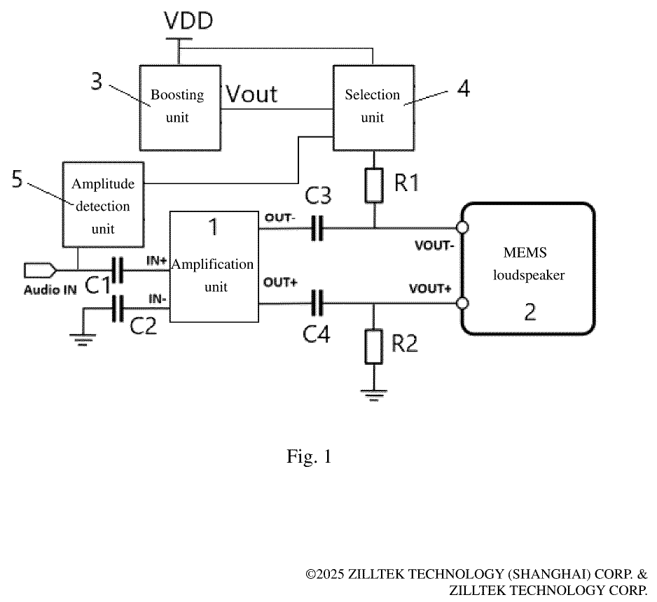

Referring to FIG. 1, a self-adaptive MEMS loudspeaker driving circuit, comprising:
an amplification unit 1, an input end of the amplification unit 1 is connected with an audio input signal Audio IN, and an output signal of the amplification unit 1 is connected with an MEMS loudspeaker 2;
a boosting unit 3, an input end of the boosting unit 3 is connected with a power supply voltage VDD, and an output end of the boosting unit 3 outputs at least one boosting voltage;
the MEMS loudspeaker 2 is selectively operable at one boosting voltage, such as a first boosting voltage Vout, or at the power supply voltage VDD.

The MEMS loudspeaker of the invention can selectively operable at the boosting voltage or at the input voltage, can adaptively select a working voltage, does not need to work under a high voltage for a long time, and is beneficial to improving the anti-electromagnetic interference capability.

In a preferred embodiment of the invention, comprising a selection unit 4, which selectively outputs the first boosting voltages Vout or the power supply voltage VDD under the action of a control signal, the selection unit 4 can be implemented as MOS transistor.

In a preferred embodiment of the invention, comprising an amplitude detection unit 5, wherein the amplitude detection unit 5 detects an amplitude of the audio input signal Audio IN, and an output terminal of the amplitude detection unit 5 outputs the control signal.

In a preferred embodiment of the invention, the amplitude detection unit 5 outputs a first signal when the amplitude of the audio input signal Audio IN is greater than a reference amplitude, and outputs a second signal when the amplitude of the audio input signal Audio IN is less than the reference amplitude, the selection unit 4 outputs a first boosting voltage Vout under action of the first signal, and outputs the power supply voltage VDD under action of the second signal.

The present invention selects whether the MEMS loudspeaker operates under the power supply voltage VDD or a higher first boosting voltage Vout based on the amplitude of the audio input signal, thereby optimizing the performance of the MEMS loudspeaker and enhancing electromagnetic interference immunity.

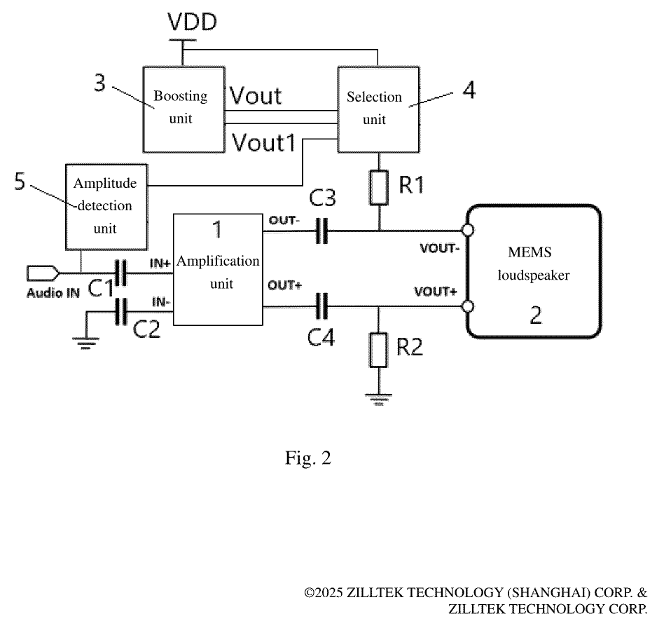

In a preferred embodiment of the invention, referring to FIG. 2, the amplitude detection unit 5 outputs a first signal when the amplitude of the audio input signal Audio IN is greater than a first reference amplitude, outputs a second signal when the amplitude of the audio input signal Audio IN is greater than the first reference amplitude and less than a second reference amplitude, and outputs a third signal when the amplitude of the audio input signal Audio IN is greater than the second reference amplitude and less than a third reference amplitude; the selection unit outputs a first boosting voltage Vout under action of the first signal, outputs a second boosting voltage Vout1 under action of the second signal, and outputs the power supply voltage VDD under action of the third signal.

By configuring stepped reference amplitudes, the working voltage of the MEMS loudspeaker can be adaptively adjusted, thereby enhancing the performance of the MEMS loudspeaker.

In a preferred embodiment of the invention, a first input terminal IN+ of the amplification unit 1 is connected to the audio input signal Audio IN through a first capacitor C1, and a second input terminal IN− of the amplification unit 1 is connected to a ground terminal through a second capacitor C2.

In a preferred embodiment of the invention, a first output terminal OUT− of the amplification unit 1 is connected to a first input terminal VOUT− of the MEMS loudspeaker 2 through a third capacitor C3, and a second output terminal OUT+ of the amplification unit 1 is connected to a second input terminal VOUT+ of the MEMS loudspeaker 2 through a fourth capacitor C4.

In a preferred embodiment of the invention, a first input terminal VOUT− of the MEMS loudspeaker 2 is connected to an output terminal of the selection unit 4 through a first resistor R1, and a second input terminal VOUT+ of the MEMS loudspeaker 2 is connected to a ground terminal through a second resistor R2.

In a preferred embodiment of the invention, the amplification unit 1 is a differential amplifier, and the boosting unit 3 is a BOOST power converter or a charge pump.

In a preferred embodiment of the invention, the power supply voltage VDD ranges from 3.3 V to 4.2 V or from 1.5 V to 3 V.

Specific embodiments of typical structures are provided through the description and drawings, and other modifications may be made based on the spirit of the present invention. Although the foregoing invention has proposed relatively preferred embodiments of the prior art, these contents are not intended to be limiting.

Various alterations and modifications will undoubtedly become apparent to those skilled in the art after reading the above description. Accordingly, the appended claims should be construed as covering all alterations and modifications that fall within the true intent and scope of the present invention. Any and all equivalents to the scope and content of the claims shall be deemed to remain within the intent and scope of the present invention.

It is claimed:

1. A self-adaptive MEMS loudspeaker driving circuit, comprising:
an amplification unit, an input end of the amplification unit is connected with an audio input signal, and an output signal of the amplification unit is connected with an MEMS loudspeaker;
a boosting unit, an input end of the boosting unit is connected with a power supply voltage, and an output end of the boosting unit outputs at least one boosting voltage;
the MEMS loudspeaker is selectively operable at one of the boosting voltages or at the power supply voltage.

2. The self-adaptive MEMS loudspeaker driving circuit of claim 1, comprising a selection unit, which selectively outputs the one of the boosting voltages or the power supply voltage under the action of a control signal.

3. The self-adaptive MEMS loudspeaker driving circuit of claim 2, comprising an amplitude detection unit, wherein the amplitude detection unit detects an amplitude of the audio input signal, and an output terminal of the amplitude detection unit outputs the control signal.

4. The self-adaptive MEMS loudspeaker driving circuit of claim 3, wherein the amplitude detection unit outputs a first signal when the amplitude of the audio input signal is greater than a reference amplitude, and outputs a second signal when the amplitude of the audio input signal is less than the reference amplitude;
the selection unit outputs a first boosting voltage under action of the first signal, and outputs the power supply voltage under action of the second signal.

5. The self-adaptive MEMS loudspeaker driving circuit of claim 3, the amplitude detection unit outputs a first signal when the amplitude of the audio input signal is greater than a first reference amplitude, outputs a second signal when the amplitude of the audio input signal is greater than the first reference amplitude and less than a second reference amplitude, and outputs a third signal when the amplitude of the audio input signal is greater than the second reference amplitude and less than a third reference amplitude;
the selection unit outputs a first boosting voltage under action of the first signal, outputs a second boosting voltage under action of the second signal, and outputs the power supply voltage under action of the third signal.

6. The self-adaptive MEMS loudspeaker driving circuit of claim 1, wherein a first input terminal of the amplification unit is connected to the audio input signal through a first capacitor, and a second input terminal of the amplification unit is connected to a ground terminal through a second capacitor.

7. The self-adaptive MEMS loudspeaker driving circuit of claim 1, wherein a first output terminal of the amplification unit is connected to a first input terminal of the MEMS loudspeaker through a third capacitor, and a second output terminal of the amplification unit is connected to a second input terminal of the MEMS loudspeaker through a fourth capacitor.

8. The self-adaptive MEMS loudspeaker driving circuit of claim 1, wherein a first input terminal of the MEMS loudspeaker is connected to an output terminal of the selection unit through a first resistor, and a second input terminal of the MEMS loudspeaker is connected to a ground terminal through a second resistor.

9. The self-adaptive MEMS loudspeaker driving circuit of claim 1, wherein the amplification unit is a differential amplifier, and the boosting unit is a BOOST power converter or a charge pump.

10. The self-adaptive MEMS loudspeaker driving circuit of claim 1, wherein the power supply voltage ranges from 3.3 V to 4.2 V or from 1.5 V to 3 V.
